(19) United States
(12) Patent Application Publication
(10) Pub. No.: US 2015/0091196 A1
(43) Pub. Date: Apr. 2, 2015

(54) MOLD LOCKS FOR LAMINATE SUBSTRATES

(71) Applicant: Thomas H. Koschmieder, Austin, TX (US)

(72) Inventor: Thomas H. Koschmieder, Austin, TX (US)

(21) Appl. No.: 14/041,968

(22) Filed: Sep. 30, 2013

(51) Int. Cl. H01L 23/31; H01L 21/66; H01L 21/56; H01L 23/13

(52) U.S. Cl. CPC H01L 23/3107; H01L 23/13; H01L 22/20; H01L 21/56
USPC 257/787; 438/5

(57) ABSTRACT

A mechanism is provided by which delamination of a substrate of a system-in-package is prevented. A mold lock feature is provided within the substrate that allows the mold compound forming the encapsulant to flow into the mold lock feature, thereby anchoring the encapsulant to the substrate. The mold lock features can be provided in areas of the substrate where higher stresses due to component configuration are predicted. Aspects of the present invention provide for a method of forming the mold lock features that is compatible with current methods of forming laminate substrates, and thereby do not require an increase in cost for manufacturing the substrate.

### BACKGROUND

1. Field

This disclosure relates generally to semiconductor device packaging, and more specifically, to providing encapsulant mold lock structures in laminate substrates.

2. Related Art

As the size of computing devices, such as smart phones, tablets, and the like, continues to decrease, there is a corresponding need for greater functionality to be provided by those computing devices. In order to satisfy that need for greater functionality, microprocessors along with other passive and active components are being combined in a single unit known as a system-in-package (SiP). The multiple components along with the microprocessor are mounted on a substrate, or stacked on the substrate, and then encapsulated using a mold compound.

One risk of including the variety of active and passive components within a single system-in-package is a possibility of delamination, or separation, of the encapsulant from the substrate. Delamination can result in a failure of the system-in-package due to, for example, changes in electrical characteristics, breaking electrical contacts, separating package components from the substrate, and allowing environmental aspects into the package to affect package components. It is therefore desirable, especially as density of components within a SiP increases, to provide a mechanism to prevent delamination of packaging encapsulant from a substrate for a system-in package.

### BRIEF DESCRIPTION OF THE DRAWINGS

The present invention may be better understood, and its numerous objects, features, and advantages made apparent to those skilled in the art by referencing the accompanying drawings.

FIG. 1 is a simplified block diagram illustrating a cross section of an example of a portion of a system-in-package.

FIG. 2 is a simplified block diagram illustrating a cross-section view of a laminate substrate usable by a system-in-package, such as those addressed by embodiments of the present invention.

FIG. 3 is a simplified block diagram illustrating a cross-section view of a laminate substrate usable by a system-in-package at a step in formation, in accordance with embodiments of the present invention.

FIG. 4 is a simplified block diagram illustrating one embodiment of a plan view of the laminate substrate illustrated in FIG. 3.

FIG. 5 is a simplified block diagram illustrating an alternative embodiment of a plan view of the laminate substrate illustrated in FIG. 3.

FIG. 6 is a simplified block diagram illustrating the cross-section view of the laminate substrate illustrated in FIG. 3 at a subsequent step in formation, in accordance with embodiments of the present invention.

FIG. 7 is a simplified block diagram illustrating a plan view of the laminate substrate illustrated in FIG. 6 according to an embodiment of the present invention

FIG. 8 is a simplified block diagram illustrating a plan view of the laminate substrate illustrated in FIG. 6, according to an alternative embodiment of the present invention.

FIG. 9 is a simplified block diagram illustrating a cross-section view of the example of the portion of system-in-package illustrated in FIG. 1 including mold-lock features of embodiments of the present invention.

FIG. 10 is a simplified block diagram illustrating a plan view of an embodiment of locking features in a laminate substrate, in accordance with embodiments of the present invention.

FIG. 11 is a simplified block diagram illustrating a plan view of an alternative embodiment of locking features in a laminate substrate, in accordance with embodiments of the present invention.

FIG. 12 is a simplified block diagram illustrating a cross section view of a substrate mold locking feature formed in accordance with embodiments of the present invention.

The use of the same reference symbols in different drawings indicates identical items unless otherwise noted. The figures are not necessarily drawn to scale.

### DETAILED DESCRIPTION

Embodiments of the present invention provide a mechanism by which delamination of a substrate of a system-in-package is prevented. A mold lock feature is provided within the substrate that allows the mold compound forming the encapsulant to flow into the mold lock feature, thereby anchoring the encapsulant to the substrate. The mold lock features can be provided in areas of the substrate where higher stresses due to component configuration are predicted. Aspects of the present invention provide for a method of forming the mold lock features that is compatible with current methods of forming laminate substrates, and thereby do not require an increase in cost for manufacturing the substrate.

FIG. 1 is a simplified block diagram illustrating a cross section of an example of a portion of a system-in-package. A substrate 110 is provided on which is mounted or formed a passive semiconductor device 120, an active semiconductor device 130, and stacked semiconductor device die 140 and 150. Passive semiconductor device 120 can include a variety of passive components including, for example, resistors, capacitors, inductors, and transformers. In general, passive semiconductor devices do not introduce net energy into a circuit. Active semiconductor device (e.g., 130) typically rely on a source of energy and include a variety of devices such as, for example, transistors and tunnel diodes. Stacked semiconductor device die 140 and 150 can include microprocessors, and other active or passive components.

An encapsulant 160 is formed by applying a mold compound over and around the various components, connections, and substrate. The mold compound can be any appropriate encapsulant including, for example, silica-filled epoxy molding compounds, plastic encapsulation resins, and other polymeric materials such as silicones, polyimides, phenolics, and polyurethanes. The mold compound can be applied by a variety of standard processing techniques used in encapsulation including, for example, printing, pressure molding, and spin application. Once the molding material is applied, the panel can be cured by exposing the materials to certain temperatures for a period of time, or by applying a curing agent, or both. In a typical encapsulation process, a depth of encapsulant 160 equals or exceeds a maximum height of structures embedded in the molding material (e.g., the height of a stack of semiconductor device die).

The dashed-line areas illustrated in FIG. 1 represents regions in which there may be issues with delamination of the cured encapsulant 160 from either components in that area or the localized surface of substrate 110. For example, region 170 is located between passive component 120 and active component 130. The difference in height of these components over the substrate can cause stress in the encapsulant material as it is applied and cured in that region. In addition, if the geometry of the components is such that the components are close, the resin/filler ration within that region can have a higher percentage of resin than the bulk area of the encapsulant, due to the resin component having a lower viscosity than the filler component, which can also cause stress in the cured encapsulant. This stress can cause the encapsulant material to separate or delaminate from the surface of the substrate under certain conditions (e.g., temperature variations).

Regions 180 and 185 represent solder bonds between passive component 120 and corresponding connectors on substrate 110. Current solder techniques can leave a residue on exposed surfaces of the solder bond. This residue can result in a poor adhesion between encapsulant 160 and the solder bond. The poor adhesion can result in a separation between the encapsulant and the solder bond that may spread to areas over the substrate 110 near the solder bond, again resulting in a delamination between the encapsulant and the substrate.

Region 190 is characterized by an overhang area formed by stacked semiconductor device die 150 over semiconductor device die 140. In certain circumstances, encapsulant may not fully fill the overhang region or stresses may occur in the encapsulant within that region due to the shape or poor coverage, again resulting in an area where a potential delamination can occur between the encapsulant and one or more of the semiconductor device die or the substrate. It is the risk of delamination between encapsulant 160 and the surface of substrate 110 within these regions that embodiments of the present invention address.

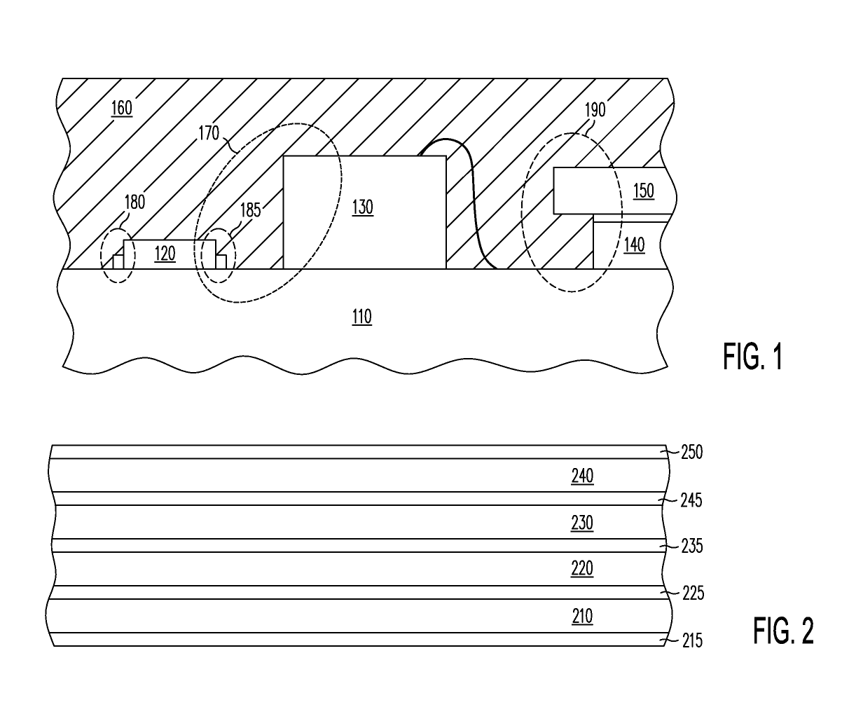

FIG. 2 is a simplified block diagram illustrating a cross-section view of a laminate substrate usable by a system-in-package, such as those addressed by embodiments of the present invention. A typical substrate is formed using multiple layers. Core layers 210, 220, 230, and 240 are typically glass-fiber-reinforced epoxy that are jacketed in metal layers 215, 225, 235, and 245 (e.g., one or more copper sheets). The portion of the substrate on which components are mounted and connected is typically a build-up layer (e.g., 250) that includes a variety of metal traces and dielectric materials between those metal traces (e.g., silica-filled epoxy). During typical formation of the substrate, vias are drilled in the core using, for example, mechanical drilling or laser drilling and is performed as each layer of the core is provided to the laminate sandwich. As each metal layer is provided to the core or the build-up layer, etching techniques known in the art are used to form the various traces that are desired. A typical overall thickness of a substrate including both the core layers and the buildup layer in BGA packaging is approximately 0.38 mm for a four-layer substrate. A typical overall thickness of a substrate including both the core layers and the buildup for a flip-chip package is approximately 0.5-1.0 mm for an eight-layer substrate.

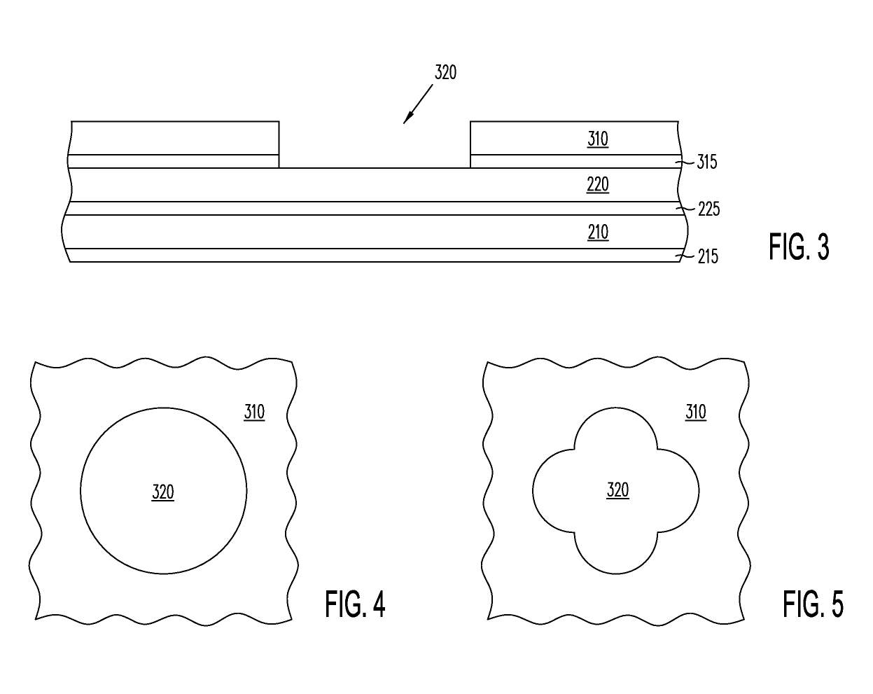

FIG. 3 is a simplified block diagram illustrating a cross-section view of a laminate substrate usable by a system-in-package at a step in formation, in accordance with embodiments of the present invention. FIG. 3 illustrates core layers 210 and 220, along with metal layers 215 and 225, as illustrated in FIG. 2 above. On substrate layer 310 and associated copper sheet layer 315, a hole 320 is formed. Hole 320 can be formed using the same drilling techniques used to form vias during formation of the substrate (e.g., mechanical or laser drilling). As will be discussed more fully below, hole 320 is intended to provide an anchoring region for the encapsulant in conjunction with a smaller diameter hole located above hole 320. Thus, hole 320 will typically be of a larger diameter than a typical via. Techniques for forming the larger hole can include, for example, using a larger drill bit than that used for via formation, or by repeatedly drilling in overlapping regions to form a larger hole area.

FIG. 4 is a simplified block diagram illustrating one embodiment of a plan view of the laminate substrate illustrated in FIG. 3. A portion of substrate layer 310 is illustrated along with hole 320. Hole 320 in FIG. 4 is provided by using a large diameter drill bit or large diameter laser drilling technique.

FIG. 5 is a simplified block diagram illustrating an alternative embodiment of a plan view of the laminate substrate illustrated in FIG. 3. A portion of substrate layer 310 is illustrated along with hole 320. Hole 320 in FIG. 5 is provided by using a smaller diameter drill bit, such as that used in formation of through vias, multiple times to form the overlapping circular structure illustrated.

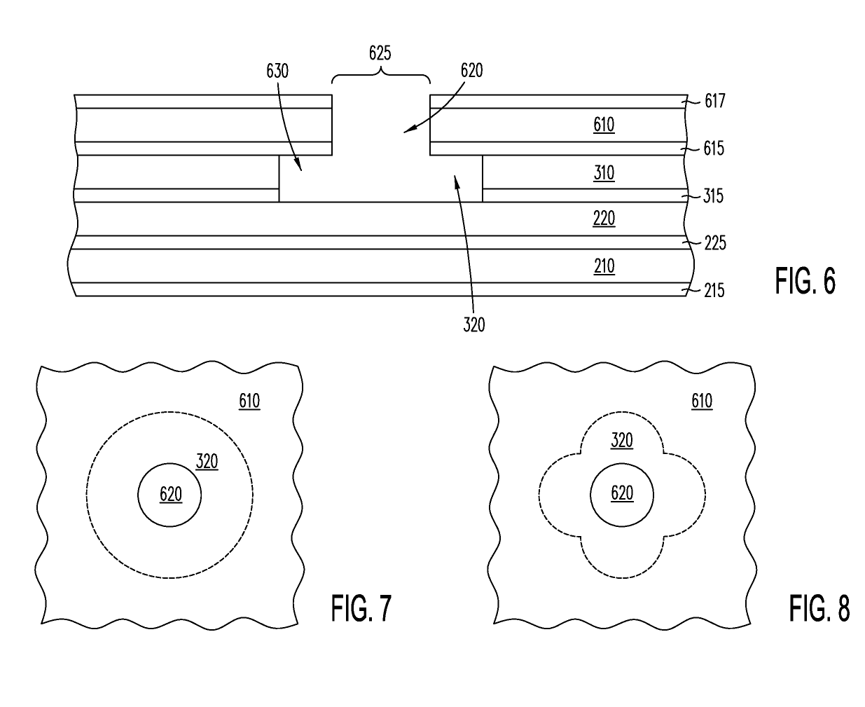

FIG. 6 is a simplified block diagram illustrating the cross-section view of the laminate substrate illustrated in FIG. 3 at a subsequent step in formation, in accordance with embodiments of the present invention. FIG. 6 illustrates additional core layer 610, along with a metal layer 615 adhesively coupled to the previously discussed core layers. In addition, build-up layer 617 is formed on or above core layer 610. On application of core layer 610, associated metal layer 615, and build up layer 617, a hole 620 is formed. As with hole 320, hole 620 can be formed using the same drilling techniques used to form vias during formation of the substrate. Hole 620 will have a smaller diameter than that of hole 320 so as to form an overhang region 630 such as that illustrated within which encapsulant can flow and be cured to anchor an encapsulant above the region including holes 620 and 320. In one embodiment, a diameter of hole 320 is greater than or equal to twice the diameter of hole 620.

FIG. 7 is a simplified block diagram illustrating a plan view of the laminate substrate illustrated in FIG. 6 according to a first embodiment of the present invention. A portion of substrate layer 610 is illustrated along with hole 620 and hole 320 as a dashed region.

FIG. 8 is a simplified block diagram illustrating a plan view of the laminate substrate illustrated in FIG. 6, according to a second embodiment of the present invention. A portion of substrate layer 610 is illustrated along with hole 620 and hole 320 as a dashed region, where hole 320 is that illustrated in FIG. 5 provided by overlapping drilled regions using a smaller drill bit.

Embodiments of the present invention are not limited by the shape of the holes provided in substrate layers 310 and 610. It is anticipated that a variety of mechanisms can be used to form the holes such that mold compound material can flow through the smaller hole in core layer 610 (and surrounding metal layers) into the region formed by hole 320. As the mold compound is cured, the material in the region formed by holes 620 and 320 can help to anchor the mold compound above those regions forming the substrate.

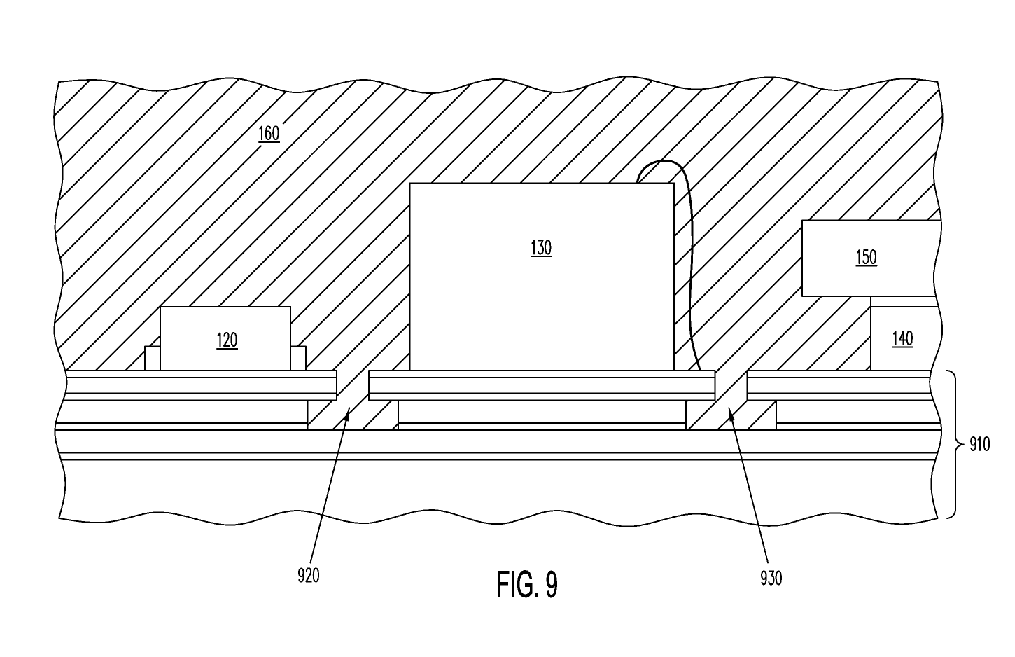

FIG. 9 is a simplified block diagram illustrating a cross-section view of the example of the portion of system-in-package illustrated in FIG. 1 including mold-lock features of embodiments of the present invention. Components 120, 130, 140, and 150 are mounted on a substrate 910. Substrate 910 is prepared using techniques such as those described above for forming mold lock features 920 and 930. Encapsulant 160 is formed by applying a mold compound to the components of the system-in-package and substrate 910. During the application of the mold compound, as discussed above, the mold compound flows into mold lock features 920 and 930. Upon curing the mold compound to form encapsulant 160, the mold compound hardens within the mold lock features, thereby anchoring the mold compound in regions where there is a risk of delamination without such mold lock features. Location of mold lock features, such as 920 and 930, can be determined through experience in finding delamination defects for a system-in-package design after manufacture, or through analytical techniques to determine high stress points in the package.

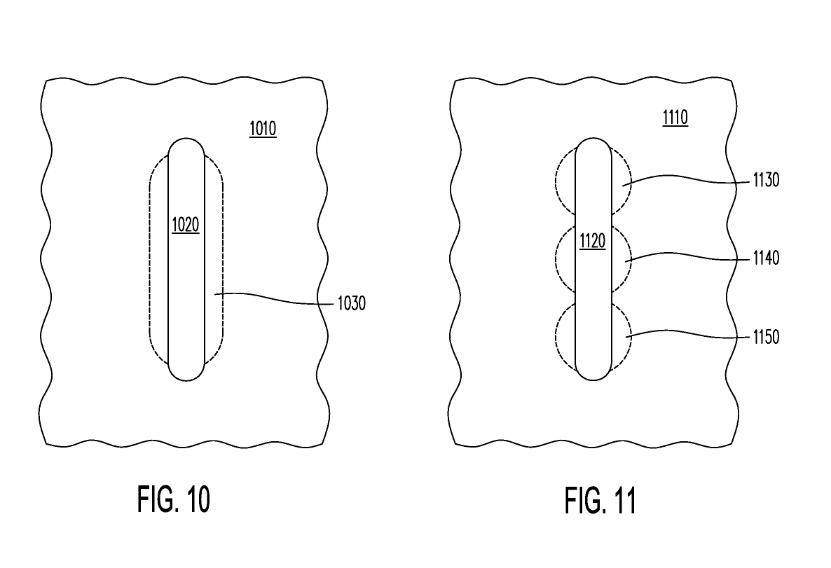

FIGS. 10 and 11 are simplified block diagrams illustrating plan views of alternative embodiments of locking features in laminate substrates, in accordance with embodiments of the present invention. FIG. 10 provides for an opening to the locking feature that is routed rather than drilled, thereby forming an elongated opening 1020 in top substrate layer 1010. In a lower layer of the substrate, an elongated opening 1030 is provided within which encapsulant can flow and formed the locking structure. FIG. 11 also provides for an opening to the locking feature that is routed rather than drilled, thereby forming an elongated opening 1120 in top substrate layer 1110. However, in a core layer beneath top substrate layer 1110, hole features 1130, 1140, and 1150 are formed within which encapsulant can flow through the routed top layer hole. Hole features 1130, 1140, and 1150 can be formed using a large drill bit or by multiple overlapping uses of a smaller drill bit. Embodiments shown in FIG. 10 and FIG. 11 are provided by way of example and are not meant to be limiting as to the variety of hole locking features that can be formed using techniques of embodiments of the present invention.

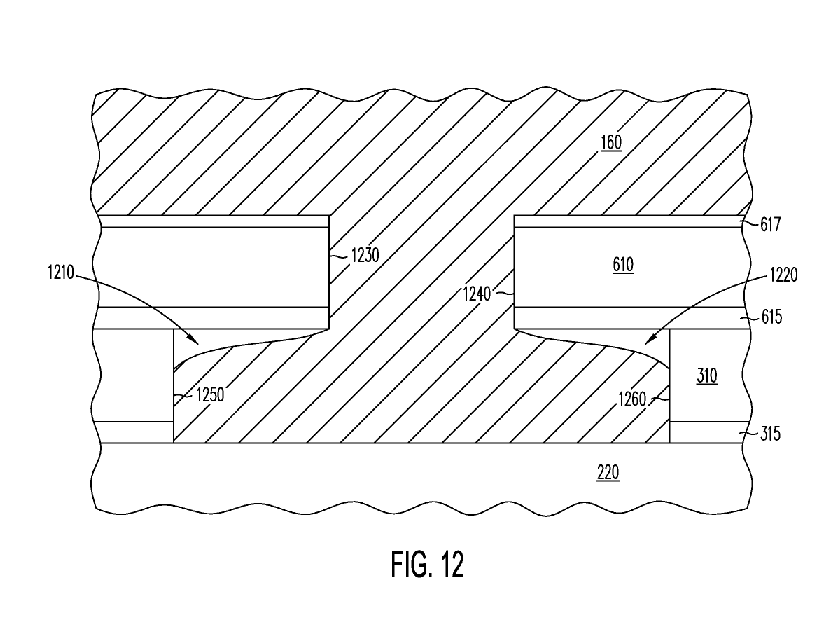

FIG. 12 is a simplified block diagram illustrating a cross section view of a substrate mold locking feature formed in accordance with embodiments of the present invention. As discussed above, the illustrated mold locking feature is formed by holes in substrate layers 310 and 610, and can include accompanying metal layers 315 and 615 and build up layer 617, all over core layer 220. Encapsulant 160 is formed over the illustrated substrate region and within the substrate mold lock feature. As discussed above, the mold compound from which encapsulant 160 is formed can include a variety of materials. Typically, those materials include a resin material that readily flows, along with a filler material that may be more viscous than the resin material, and therefore may not flow into certain regions as readily. Thus, it may occur that the mold compound material flowing into the mold lock feature is a higher percentage of resin than the bulk material outside the mold lock feature. Since the core material of the substrate typically includes resin as well, it is not anticipated that a higher percentage of resin in the mold lock feature will decrease effectiveness of the mold lock feature.

Further, given the viscosity of the mold compound, it may occur that gaps 1210 and 1220 beneath the overhang of core layer 610 and metal layer 615 may form. Once the mold material is cured, however, it is believed that the adhesion between the encapsulant and the neighboring core layers in areas such as 1230, 1240, 1250, and 1260, will continue to result in an effective anchor for the mold lock feature.

By now it should be appreciated that there has been provided a semiconductor device package that includes a substrate and an encapsulant formed over a major surface of the substrate. The substrate includes a first layer having a first opening formed with a first opening area, a second layer having a second opening formed with a second opening area, and a third layer provided below the second layer in a laminate stack forming the substrate. The second opening area is less than the first opening area. The second layer is provided above the first layer in a laminate stack that forms the substrate. The second opening is located in a position that provides access to the first opening from the major surface of the substrate. The third layer covers the side of the first opening opposite the second layer. The encapsulant is further formed within the first and second openings.

In one aspect of the above embodiment, the first layer includes a first core layer and a first metal layer and the second layer includes a second core layer and a second metal layer. In a further aspect, the first and second core layers include a glass-fiber-reinforced epoxy, and the encapsulant within the first and second openings includes a resin that can bind to the first and second core layers.

In another aspect of the above embodiment, the first opening is a circular shape having a first diameter, the second opening is a circular shape having a second diameter, and the first diameter is greater than or equal to twice the second diameter. In a further aspect, the first and second openings are formed using one or more of a mechanical or laser drilling process. In another further aspect, the second opening is a same diameter as a through via in the second layer. In another further aspect, the mechanical or laser drilling process is a same process as that used for formation of vias in the substrate.

In another aspect of the above embodiment, the second opening is a circular shape having a second diameter, the first opening is a shape formed from overlapping circular shapes of the second diameter, and a longest dimension of the first opening is greater than or equal to two times the second diameter. In still another aspect of the above embodiment, the first opening has a first length and a first width, the second opening has a second length and a second width, and the first width is greater than or equal to twice the second width. In yet another aspect of the above embodiment, the first opening is formed using a drilling process to form one or more circular shapes or overlapping circular shapes, and the second opening is formed using a routing process to form a shape having a first length and a first width. In still another aspect of the above embodiment, the semiconductor device package further includes one or more of a passive semiconductor device, an active semiconductor device, or a semiconductor device die mounted on the major surface of the substrate and electrically coupled to one or more contacts on the major surface of the substrate. The encapsulant is further formed over and around the one or more of the passive semiconductor device, active semiconductor device, or semiconductor device die.

Another embodiment of the present invention provides for a method for forming a semiconductor device package. The method includes: forming a first opening in a first layer of a substrate; forming a second opening in a second layer of the substrate, where the first opening has a first opening area, the second opening has a second opening area, and the second opening area is less than the first opening area; forming the substrate to include the first and second layers and a third layer, where the second opening is located in a position that provides access to the first opening from a major surface of the substrate, and the third layer is provided below the second layer in a laminate stack forming the substrate and covering the side of the first opening opposite the second layer; and, forming an encapsulant over the major surface of the substrate and within the first and second openings.

In one aspect of the above embodiment, the first layer includes a first core layer and a first metal layer, and the second layer includes a second core layer and a second metal layer. In another aspect of the above embodiment, forming the first opening includes drilling a circular shape having a first diameter, forming the second opening includes drilling a circular shape having a second diameter, and the first diameter is greater than or equal to twice the second diameter. In a further aspect, the drilling includes either a mechanical or laser drilling process. In still a further aspect, the mechanical or laser drilling process is the same process as that used for formation of vias in the substrate.

In another aspect of the above embodiment, forming the second opening includes drilling a circular shape using a drill bit having a second diameter, and forming the first opening includes drilling overlapping circular shapes using the drill bit having the second diameter.

Another aspect of the above embodiment includes mounting one or more of a passive semiconductor device, an active semiconductor device, or a semiconductor device die on the major surface of the substrate, and forming the encapsulant over and around the one or more of the passive semiconductor device, active semiconductor device, or the semiconductor device die. In a further aspect, forming the first and second opening further includes determining a location within the semiconductor device package subject to an increased likelihood of delamination between the encapsulant and the major surface of the substrate, and forming the first and second openings in or around the determined location. In still a further aspect, determining the location within the semiconductor device package subject to an increased likelihood of delamination includes locating one or more of exposed solder joints, semiconductor device components of differing heights above the substrate and in close proximity, and regions of stress between the substrate and the encapsulant.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, the narrow hole of the top of the substrate mold locking feature can pass through more than one core layer, and similarly the wider hole at the base of the mold locking feature can pass through more than one core layer, as the application suggests. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A semiconductor device package comprising:
a substrate comprising
a first layer having a first opening formed with a first opening area,
a second layer having a second opening formed with a second opening area,
wherein
the second opening area is less than the first opening area,
the second layer is provided above the first layer in a laminate stack forming the substrate,
the second opening is located in a position that provides access to the first opening from a major surface of the substrate, and
a third layer provided below the first layer in the laminate stack forming the substrate and covering the side of the first opening opposite the second layer; and
encapsulant formed over the major surface of the substrate and within the first and second openings.

2. The semiconductor device package of claim 1, wherein
the first layer comprises a first core layer and a first metal layer; and
the second layer comprises a second core layer and a second metal layer.

3. The semiconductor device package of claim 2, wherein
the first and second core layers comprise a glass-fiber-reinforced epoxy, and
the encapsulant within the first and second openings comprises a resin that binds to the first and second core layers.

4. The semiconductor device package of claim 1, wherein
the first opening comprises a circular shape having a first diameter,
the second opening comprises a circular shape having a second diameter, and
the first diameter is greater than or equal to twice the second diameter.

5. The semiconductor device package of claim 4 wherein the first and second openings are formed using one or more of a mechanical or laser drilling process.

6. The semiconductor device package of claim 5 wherein the second opening comprises a same diameter as a through via in the second layer.

7. The semiconductor device package of claim 5 wherein the mechanical or laser drilling process is a same process as that used for formation of vias in the substrate.

8. The semiconductor device package of claim 1, wherein
the second opening comprises a circular shape having a second diameter,
the first opening comprises a shape formed from overlapping circular shapes of the second diameter, and
a longest dimension of the first opening is greater than or equal to two times the second diameter.

9. The semiconductor device package of claim 1, wherein
the first opening has a first length and a first width,
the second opening has a second length and a second width, and
the first width is greater than or equal to twice the second width.

10. The semiconductor device package of claim 1, wherein
the first opening is formed using a drilling process to form one or more circular shapes or overlapping circular shapes, and
the second opening is formed using a routing process to form a shape having a first length and a first width.

11. The semiconductor device package of claim 1 further comprising:
one or more of a passive semiconductor device, an active semiconductor device, or a semiconductor device die mounted on the major surface of the substrate and electrically coupled to one or more contacts on the major surface of the substrate,
wherein
the encapsulant is further formed over and around the one or more of the passive semiconductor device, active semiconductor device, or semiconductor device die.

12. A method for forming a semiconductor device package comprising:
forming a first opening in a first layer of a substrate;
forming a second opening in a second layer of the substrate, wherein
the first opening comprises a first opening area,
the second opening comprises a second opening area,
the second opening area is less than the first opening area;
forming the substrate comprising the first and second layers and a third layer of the substrate, wherein
the second opening is located in a position that provides access to the first opening from a major surface of the substrate, and
the third layer is provided below the first layer in a laminate stack forming the substrate and covering the side of the first opening opposite the second layer; and
forming an encapsulant over the major surface of the substrate and within the first and second openings.

13. The method of claim 12, wherein
the first layer comprises a first core layer and a first metal layer, and
the second layer comprises a second core layer and a second metal layer.

14. The method of claim 12, wherein
said forming the first opening comprises drilling a circular shape having a first diameter,
said forming the second opening comprises drilling a circular shape having a second diameter, and
the first diameter being greater than or equal to twice the second diameter.

15. The method of claim 14 wherein said drilling comprises a mechanical or laser drilling process.

16. The method of claim 15 wherein the mechanical or laser drilling process is a same process as that used for formation of vias in the substrate.

17. The method of claim 12, wherein
said forming the second opening comprises drilling a circular shape using a drill bit having a second diameter, and
said forming the first opening comprises drilling overlapping circular shapes using the drill bit having the second diameter.

18. The method of claim 12 further comprising:
mounting one or more of a passive semiconductor device, an active semiconductor device, or a semiconductor device die on the major surface of the substrate; and
forming the encapsulant over and around the one or more of the passive semiconductor device, active semiconductor device, or semiconductor device die.

19. The method of claim 18, wherein said forming the first and second opening further comprises:
determining a location within the semiconductor device package subject to an increased likelihood of delamination between the encapsulant and the major surface of the substrate; and
forming the first and second opening in or around the determined location.

20. The method of claim 19 wherein said determining the location within the semiconductor device package subject to an increased likelihood of delamination comprises:
locating one or more of exposed solder joints, semiconductor device components of differing heights above the substrate and in close proximity, and regions of stress between the substrate and the encapsulant.
